(19) United States
(12) Patent Application Publication
(10) Pub. No.: US 2026/0096196 A1
(43) Pub. Date: Apr. 2, 2026

(54) TRANSISTOR AND SEMICONDUCTOR DEVICE INCLUDING THE SAME

(71) Applicant: Samsung Electronics Co., Ltd., Suwon-si (KR)

(72) Inventor: Hwayeong LEE, Suwon-si (KR)

(73) Assignee: Samsung Electronics Co., Ltd., Suwon-si (KR)

(21) Appl. No.: 19/204,845

(22) Filed: May 12, 2025

(30) Foreign Application Priority Data
Oct. 2, 2024 (KR) 10-2024-0134067

(51) Int. Cl. H10D 84/85; H10D 30/01; H10D 30/63; H10D 62/40; H10D 62/83; H10D 64/27; H10D 84/01

(52) U.S. Cl. CPC H10D 84/85; H10D 30/63; H10D 62/40; H10D 62/83; H10D 64/518; H10D 30/025; H10D 84/0195

(57) ABSTRACT

A transistor according to at least one example embodiment includes a first transistor located on a base layer and including a first channel region, the first channel region including at least one of crystalline or polycrystalline silicon, and a second transistor located on the first transistor, overlapping at least a portion of the first transistor in a height direction, the second transistor including a second channel region including an oxide semiconductor.

### CROSS-REFERENCE TO RELATED APPLICATION

This application claims priority to and the benefit of Korean Patent Application No. 10-2024-0134067 filed at the Korean Intellectual Property Office on Oct. 2, 2024, the entire contents of which are incorporated herein by reference.

### BACKGROUND

### 1. Field

The present disclosure relates to a transistor and a semiconductor device including the same.

### 2. Description of the Related Art

A transistor has three terminals: a gate terminal, a source terminal, and a drain terminal, and current may flow through a channel region containing a semiconductor based on an application of a charge via the gate terminal.

The semiconductor used in the channel region of the transistor may be (or include) a semiconductive material, such as one or more of amorphous silicon, crystalline silicon, oxide semiconductor, etc., with each material having advantages and disadvantages compared to the others.

### SUMMARY

The embodiments attempt to provide a transistor and a semiconductor device including the same capable of preventing performance degradation.

However, the embodiments of the present disclosure are not limited to those mentioned above and may be variously extended in the scope of the technical ideas included in the present disclosure.

A transistor according to at least one example embodiment includes a first transistor located on a base layer and including a first channel region, the first channel region including at least one of crystalline or polycrystalline silicon, and a second transistor located on the first transistor, overlapping at least a portion of the first transistor in a height direction, the second transistor including a second channel region including an oxide semiconductor.

A transistor according to at least one example embodiment includes a a first transistor on a base layer, the first transistor including a first channel region and first source drain regions located, respectively, under and over the first channel region in a height direction, the first channel region including at least one of a crystalline or polycrystalline silicon, and a a second transistor on the base layer and located on a side surface of the first transistor, the second transistor including a second channel region and second source drain regions located, respectively, under and over the second channel region in the height direction, the second channel region including an oxide semiconductor.

A semiconductor device according to at least one example embodiment includes a transistor structure including a first transistor and a second transistor on a base layer, the first transistor including a first channel region, the second transistor including a second channel region, the second transistor located over the first transistor and at least partially overlapping the first transistor in a height direction, and a memory cell connected to the transistor structure. The first channel region includes at least one of crystalline or polycrystalline silicon, and the second channel region includes an oxide semiconductor.

A method of producing the transistor according to at least one example embodiment, includes forming a first semiconductor layer such that the first semiconductor layer includes an upper region and lower region and a middle region between the upper and lower regions, the middle region including at least one of a crystalline or polycrystalline silicon; forming a first semiconductor pattern by etching the first semiconductor layer; forming a first insulating layer on the first semiconductor pattern; forming a first gate metal layer on the first insulating layer; forming, after the forming of the first semiconductor pattern, a second semiconductor layer such that the second semiconductor layer includes an upper region and lower region and a middle region between the upper and lower regions, the middle region including an oxide semiconductor; forming a second semiconductor pattern by etching the second semiconductor layer; forming a second insulating layer on the second semiconductor pattern; and forming a second gate metal layer on the second insulating layer.

The method may further include forming an insulating layer on at least one of the first gate metal layer or the second gate metal layer.

The forming of the first semiconductor pattern and the forming of the second semiconductor pattern may, respectively, include forming first source drain regions from a remainder of the upper and lower region of the first semiconductor pattern after etching and forming second source drain regions from a remainder of the upper and lower region of the second semiconductor pattern after etching; and the method may further include forming a connection electrode such that the connection electrode electrically connects one of the first source drain regions to one of the second source drain regions.

The method may further include forming a memory cell such that the memory cell is electrically connected to the connection electrode.

According to some example embodiments, it is possible to provide a transistor and a semiconductor device including the same capable of preventing performance degradation.

However, embodiments of the present disclosure are not limited to those mentioned above and may be variously extended in the scope of the technical ideas included in the present disclosure.

### BRIEF DESCRIPTION OF THE DRAWINGS

The various features and advantages of the non-limiting embodiments herein may become more apparent upon review of the detailed description in conjunction with the accompanying drawings. The accompanying drawings are merely provided for illustrative purposes and should not be interpreted to limit the scope of the claims. The accompanying drawings are not to be considered as drawn to scale unless explicitly noted. For purposes of clarity, various dimensions of the drawings may have been exaggerated.

FIG. 1 is a schematic cross-sectional view of a transistor according to at least one example embodiment.

FIG. 2 is a schematic cross-sectional view of a transistor according to at least one example embodiment.

FIG. 3 is a schematic cross-sectional view of a transistor according to at least one example embodiment.

FIG. 4 is a schematic cross-sectional view of a transistor according to at least one example embodiment.

FIG. 5 is a schematic cross-sectional view illustrating a semiconductor device according to at least one example embodiment.

FIG. 6 is a schematic perspective view illustrating a portion of a semiconductor device according to at least one example embodiment.

FIGS. 7 and 8 are circuit diagrams for operations of a semiconductor device according to at least one example embodiment.

FIG. 9 is a schematic cross-sectional view of a semiconductor device according to at least one example embodiment.

FIG. 10 is a schematic cross-sectional view of a semiconductor device according to at least one example embodiment.

FIGS. 11 to 22 are cross-sectional views illustrating a method for manufacturing a semiconductor device according to at least one example embodiment.

FIGS. 23 to 30 are cross-sectional views illustrating a method for manufacturing a semiconductor device according to at least one example embodiment.

### DETAILED DESCRIPTION

The present disclosure will be described in detail hereinafter with reference to the accompanying drawings, in which embodiments of the present disclosure are shown. As those skilled in the art would realize, the described embodiments may be modified in various different ways, all without departing from the spirit or scope of the present disclosure.

The drawings and description are to be regarded as illustrative in nature and not restrictive, and like reference numerals designate like elements throughout the specification.

The accompanying drawings are intended only to facilitate understanding of the embodiments disclosed in this specification, and it is to be understood that the technical ideas disclosed herein are not limited by the accompanying drawings and include all modifications, equivalents, or substitutions that are within the range of the ideas and technology of the present disclosure.

Further, since sizes and thicknesses of components shown in the accompanying drawings may be arbitrarily given to facilitate understanding and ease of description, the disclosure is not limited to the illustrated sizes and thicknesses. In the drawings, the thicknesses of layers and regions are exaggerated for clarity. In the drawings, to facilitate understanding and ease of description, the thicknesses of some layers and regions may be exaggerated. Additionally, when the terms “about” or “substantially” are used in this specification in connection with a numerical value and/or geometric terms, it is intended that the associated numerical value includes a manufacturing tolerance (e.g., ±10%) around the stated numerical value. Further, regardless of whether numerical values and/or geometric terms are modified as “about” or “substantially,” it will be understood that these values should be construed as including a manufacturing or operational tolerance (e.g., ±10%) around the stated numerical values and/or geometry.

It should be understood that when an element such as a layer, film, region, or substrate is referred to as being “on” another element, it may be directly on the other element or intervening elements may also be present. In contrast, when an element is referred to as being “directly on” another element, there are no intervening elements present. Further, when an element is referred to as being “on” or “above” a reference element, it may be positioned above or below the reference element, and it may not necessarily be referred to as being positioned “on” or “above” it in a direction opposite to gravity. Additionally, spatially relative terms, such as upper, lower, side, etc. are represented based on the direction illustrated in the drawings and may be represented otherwise when the orientation of the corresponding object changes. In other words, such spatially relative terms are intended to encompass different orientations of the device in use or operation in addition to the orientation depicted in the figures, such that the device may be otherwise oriented (rotated 90 degrees or at other orientations) and the spatially relative terms used herein interpreted accordingly.

Therefore, unless explicitly stated to the contrary, the word “comprise” and variations such as “comprises” and “comprising” should be understood to imply the inclusion of stated elements but not the exclusion of any other elements.

In addition, the phrase “on a plane” means a view from a position above the object (e.g., from the top), and the phrase “in a cross-section” means a view of a cross-section of the object which is vertically cut from the side.

Throughout the specification, the term “connected” does not mean only that two or more components are directly connected, but may also mean that two or more components are indirectly connected through another component, that two or more components are electrically connected as well as physically connected, or that two or more components are referred to by different names but are united by location or function.

Hereinafter, various embodiments and variations will be described in detail with reference to the drawings.

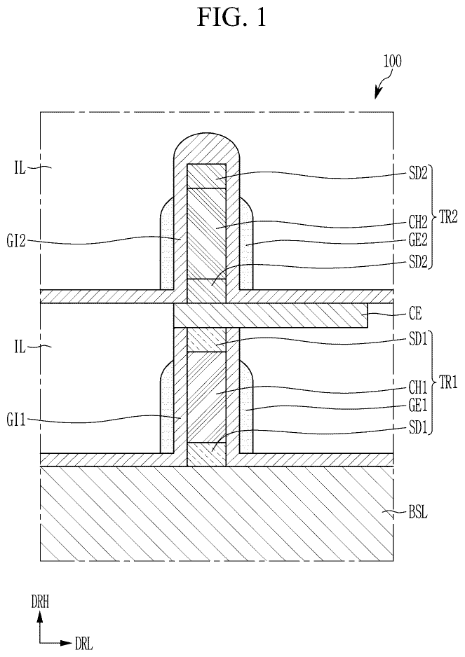

Referring to FIG. 1, a transistor 100 according to at least one example embodiment is described. FIG. 1 is a schematic cross-sectional view of a transistor according to at least one example embodiment.

Referring to FIG. 1, the transistor 100 according to at least one example embodiment may include a first transistor TR1 and a second transistor TR2 on a base layer BSL.

The base layer BSL may be a substrate. For example, the base layer BSL may be a semiconductor substrate or an insulating substrate. Additionally, in at least some embodiments, the substrate may include a semiconductor layer and/or an insulating layer.

The first transistor TR1 may include a first channel region CH1 extending in a height direction DRH, a pair of first source drain regions SD1 located on opposite sides of the first channel region CH1 and spaced apart in the height direction DRH, and a first gate electrode GE1 located on a side surface of the first channel region CH1 with a first gate insulating film GI1 interposed between the first channel region CH1 and the first gate electrode GE1 in a planar direction DRL. In the illustrated example embodiment, the first gate electrode GE1 is illustrated as being on both sides of the first channel region CH1, but the example embodiments are not limited thereto, and the first gate electrode GE1 may surround the first channel region CH1 and/or be on one side of the first channel region CH1.

The second transistor TR2 may include a second channel region CH2 extending in the height direction DRH, a pair of second source drain regions SD2 located on opposite sides of the second channel region CH2 in the height direction DRH, and a second gate electrode GE2 located on a side surface of the second channel region CH2 with a second gate insulating film GI2 interposed between the second channel region CH2 and the second gate electrode GE2 in the planar direction DRL. In the illustrated example embodiment, the second gate electrode GE2 is illustrated as being on both sides of the second channel region CH2, but the example embodiments are not limited thereto, and the second gate electrode GE2 may surround the second channel region CH2 or be on one side of the second channel region CH2.

In the height direction DRH, the second transistor TR2 may be located on (e.g., over) the first transistor TR1. In other words, in at least some example embodiments, the first transistor TR1 and the second transistor TR2 may overlap in the height direction DRH.

The first channel region CH1 of the first transistor TR1 and the second channel region CH2 of the second transistor TR2 may include different types of semiconductors. For example, in at least one example embodiment, the first channel region CH1 may include silicon and the second channel region CH2 may include an oxide semiconductor. For example, in at least one example embodiment, the first channel region CH1 may include one or more of crystalline silicon and/or polycrystalline silicon. Additionally, in at least one example embodiment, the second channel region CH2 may include at least one of indium gallium zinc oxide (IGZO), zinc oxide (ZnO), zinc tin oxide (ZTO), indium gallium tin oxide (IGTO), and/or indium zinc oxide (IZO).

The first channel region CH1 of the first transistor TR1 and the second channel region CH2 of the second transistor TR2 may have different conductivity types. For example, the first channel region CH1 of the first transistor TR1 may include a p-type semiconductor, and the second channel region CH2 of the second transistor TR2 may include an n-type semiconductor. Thereby, the first transistor TR1 may be a p-type transistor, and the second transistor TR2 may be an n-type transistor.

The first source drain regions SD1 may include a higher concentration of impurities (e.g., as dopants) than the first channel region CH1, and the second source drain regions SD2 may include a higher concentration of impurities (e.g., as dopants) than the second channel region CH2. For example, the first source drain regions SD1 may be doped with an n-type impurity, and the second source drain regions SD2 may be doped with a p-type impurity, but the example embodiments are not limited thereto.

In at least one example embodiment, the height direction DRH, the first channel region CH1 may not overlap the first gate electrode GE1, and in the planar direction DRL, the first channel region CH1 may overlap the first gate electrode GE1.

The first channel region CH1 may overlap the first source drain regions SD1 in the height direction DRH.

The first channel region CH1 of the first transistor TR1 may extend parallel (or substantially parallel) to the height direction DRH.

Similarly, in the height direction DRH, the second channel region CH2 may not overlap the second gate electrode GE2, and in the planar direction DRL, the second channel region CH2 may overlap the second gate electrode GE2.

The second channel region CH2 may overlap the second source drain regions SD2 in the height direction DRH.

The second channel region CH2 of the second transistor TR2 may be extended parallel (or substantially parallel) to the height direction DRH.

In at least some example embodiments, width of the first channel region CH1 of the first transistor TR1 (e.g., in the planar direction DRL) may be different from the width of the second channel region CH2 of the second transistor TR2, and/or the length of the first channel region CH1 of the first transistor TR1 (e.g., in a direction perpendicular to the height direction DRH and the planar direction DRL) may be different from the length of the second channel region CH2 of the second transistor TR2.

One first source drain region SD1 (of the first source drain regions SD1 of the first transistor TR1) and one second source drain region SD2 (of the source drain regions SD2 of the second transistor TR2) may be connected to each other, and thus, the first transistor TR1 and the second transistor TR2 may form a complementary metal-oxide-semiconductor (CMOS) transistor.

A connection electrode CE may be located between the one first source drain region SD1 of the first transistor TR1 and the one source drain region SD2 of the second transistor TR2 connected to each other.

The first transistor TR1 and the second transistor TR2 may each be surrounded by an insulating layer IL, and the first transistor TR1 and the second transistor TR2 may be electrically separated from the outside by the insulating layer IL.

As noted above, according to at least one example embodiment, the first channel region CH1 of the first transistor TR1, which is a p-type transistor, may include crystalline silicon, and the second channel region CH2 of the second transistor TR2, which is an n-type transistor, may include an oxide semiconductor.

The transistors including oxide semiconductors may be formed by low-temperature processes and have lower leakage current than transistors including crystalline silicon. However, in the case of transistors including oxide semiconductors, hole movement and formation is limited, thus making it difficult to include oxide semiconductors in the channels of p-type transistors wherein holes are the primary charge carriers.

For transistors including crystalline silicon, mobility may be higher than for transistors including oxide semiconductors. However, in the case of transistors including crystalline silicon, the process temperature for crystallizing silicon is relatively high, so elements formed prior to the formation of the transistor channel may be damaged by the higher process temperature applied during crystallization.

As described above, according to the transistor 100 in the example embodiments, the first channel region CH1 of the first transistor TR1, which is a p-type transistor, includes crystalline and/or polycrystalline silicon, thereby increasing the mobility of the first transistor TR1 and preventing (or reducing) the movement and formation of holes from being limited, and the second channel region CH2 of the second transistor TR2, which is an n-type transistor, includes an oxide semiconductor, thereby reducing the leakage current of the second transistor TR2, and since the manufacturing of the second transistor TR2 does not include a high process temperature, it is possible to reduce damage to the first transistor TR1 and other elements located under the second transistor TR2 during formation of the second transistor TR2.

According to the transistor 100, the second transistor TR2 may be located on the first transistor TR1 in the height direction DRH, so that the planar area occupied by the first transistor TR1 and the second transistor TR2 may be reduced, and a vertical channel CMOS having a channel direction parallel to the height direction DRH may be formed in a narrow planar area.

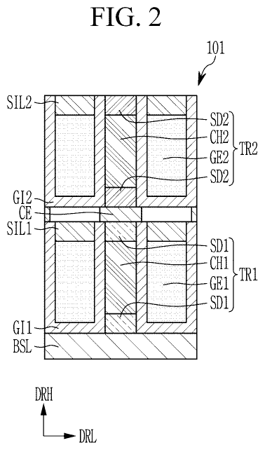

Referring to FIG. 2, a transistor 101 according to at least one example embodiment is described. FIG. 2 is a schematic cross-sectional view of a transistor according to at least one example embodiment.

Referring to FIG. 2, the transistor 101 according to the at least one example embodiment is similar to the transistor 100 according to the embodiment described above. Therefore, the descriptions of the same components may be omitted, and the differences thereto are primarily discussed.

A transistor 101 according to at least one example embodiment may include the first transistor TR1 and the second transistor TR2 on the base layer BSL.

In the height direction DRH, the second transistor TR2 may be located on the first transistor TR1.

The first transistor TR1 may include the first channel region CH1 extending in a height direction DRH, first source drain regions SD1 located on opposite sides of the first channel region CH1 in the height direction DRH, and a first gate electrode GE1 located on a side surface of the first channel region CH1 with the first gate insulating film GI1 interposed between the first channel region CH1 and the first gate electrode GE1 in a planar direction DRL.

The second transistor TR2 may include a second channel region CH2 extending in the height direction DRH, second source drain regions SD2 located on opposite sides of the second channel region CH2 in the height direction DRH, and a second gate electrode GE2 located on a side surface of the second channel region CH2 with a second gate insulating film GI2 interposed between the second channel region CH2 and the second gate electrode GE2 in the planar direction DRL.

Unlike the transistor 100, the gate electrodes GE1 and GE2 may fill a at least partially region between the channel regions CH1 and CH2 and adjacent channel regions CH1 and CH2 (not illustrated), and separation insulating layers SIL1 and SIL2 may be located on the gate electrodes GE1, GE2. The separation insulating layer SIL1 may electrically isolate the connection electrodes CE and the gate electrodes GE1 and GE2.

Like the transistor 100, first transistor TR1 of the transistor 101 may be a p-type transistor, and the second transistor TR2 of the transistor 101 may be an n-type transistor. For example, the first channel region CH1 of the first transistor TR1 and the second channel region CH2 of the second transistor TR2 may have different conductivity types; and/or, the first channel region CH1 of the first transistor TR1 may include a p-type semiconductor, and the second channel region CH2 of the second transistor TR2 may include an n-type semiconductor.

In other words, the first channel region CH1 of the first transistor TR1 and the second channel region CH2 of the second transistor TR2 may include different types of semiconductors. The first channel region CH1 of the first transistor TR1 may include silicon (e.g., crystalline and/or polycrystalline silicon); and the second channel region CH2 of the second transistor TR2 may include an oxide semiconductor.

The first source drain regions SD1 may include a higher concentration of impurities (e.g., as dopants) than the first channel region CH1, and the second source drain regions SD2 may include a higher concentration of impurities (e.g., as dopants) than the second channel region CH2. For example, the first source drain regions SD1 may be doped with an n-type impurity, and the second source drain regions SD2 may be doped with a p-type impurity, but the example embodiments are not limited thereto.

According to the transistor 101, the first channel region CH1 of the first transistor TR1, which is a p-type transistor includes crystalline and/or polycrystalline silicon, thereby increasing the mobility of the first transistor TR1 and preventing (or reducing) the movement and formation of holes from being limited, and the second channel region CH2 of the second transistor TR2, which is an n-type transistor, includes an oxide semiconductor, thereby reducing the leakage current of the second transistor TR2, and since the manufacturing of the second transistor TR2 does not include a high process temperature, it is possible to reduce damage to the first transistor TR1 and other elements located under the second transistor TR2 during formation of the second transistor TR2.

The second transistor TR2 may be located on the first transistor TR1 in the height direction DRH, so that the planar area occupied by the first transistor TR1 and the second transistor TR2 may be reduced, and the vertical channel CMOS having a channel direction parallel to the height direction DRH may be formed in a narrow planar area.

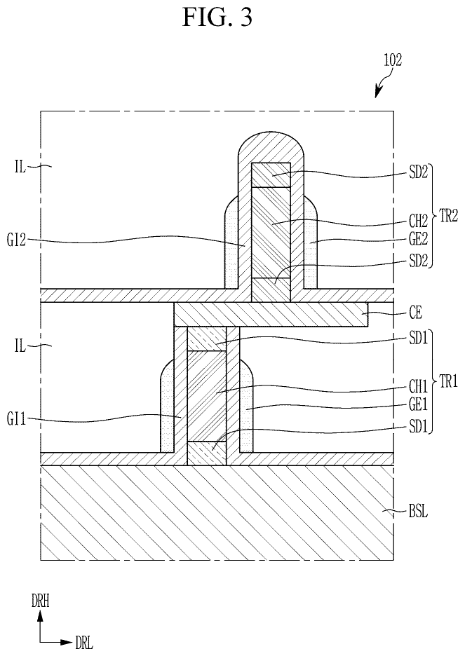

Referring to FIG. 3, the transistor 102 according to at least one example embodiment is described. FIG. 3 is a schematic cross-sectional view of a transistor according to at least one example embodiment.

Referring to FIG. 3, the transistor 102 according to the at least one example embodiment is similar to the transistor 100 and 101 according to the example embodiments described above. Therefore, detailed descriptions of the same components may be omitted and the differences mainly described below.

Referring to FIG. 3, the transistor 102 according to at least one example embodiment may include the first transistor TR1 and the second transistor TR2 on the base layer BSL.

In the height direction DRH, the second transistor TR2 may be located on the first transistor TR1.

Unlike the transistor 100, the center of the first transistor TR1 may be skewed from the center of the second transistor TR2. For example, at least a portion of the first transistor TR1 and the second transistor TR2 may not overlap in the height direction DRH. For example, the channel regions CH1 and CH2 of the first transistor TR1 and the second transistor TR2 may not overlap each other in the height direction DRH, and parts of the gate electrodes GE1 and GE2 of the first transistor TR1 and the second transistor TR2 may overlap each other.

The first transistor TR1 may be a p-type transistor, and the second transistor TR2 may be an n-type transistor. For example, the first channel region CH1 of the first transistor TR1 and the second channel region CH2 of the second transistor TR2 may have different conductivity types; and/or the first channel region CH1 of the first transistor TR1 may include a p-type semiconductor, and the second channel region CH2 of the second transistor TR2 may include an n-type semiconductor.

The first channel region CH1 of the first transistor TR1 and the second channel region CH2 of the second transistor TR2 may include different types of semiconductors. The first channel region CH1 of the first transistor TR1 may include silicon (e.g., crystalline and/or polycrystalline silicon); and/or the second channel region CH2 of the second transistor TR2 may include an oxide semiconductor.

The first source drain regions SD1 may include a higher concentration of impurities (e.g., as dopants) than the first channel region CH1, and the second source drain regions SD2 may include a higher concentration of impurities (e.g., as dopants) than the second channel region CH2. For example, the first source drain regions SD1 may be doped with an n-type impurity, and the second source drain regions SD2 may be doped with a p-type impurity, but the embodiment is not limited thereto.

According to the transistor 102 in the embodiment, the first channel region CH1 of the first transistor TR1, which is a p-type transistor, includes crystalline and/or polycrystalline silicon, thereby increasing the mobility of the first transistor TR1 and preventing (or reducing) the movement and formation of holes from being limited, and the second channel region CH2 of the second transistor TR2, which is an n-type transistor, includes an oxide semiconductor, thereby reducing the leakage current of the second transistor TR2, and since the manufacturing of the second transistor TR2 does not include a high process temperature, it is possible to reduce damage to the first transistor TR1 and other elements located under the second transistor TR2 during formation of the second transistor TR2.

The second transistor TR2 may be located on the first transistor TR1 in the height direction DRH, so that the planar area occupied by the first transistor TR1 and the second transistor TR2 may be reduced, and a vertical channel CMOS having a channel direction parallel to the height direction DRH may be formed in a narrow planar area.

Many of the features of the transistors 100 and 101 according to the embodiments described above are applicable to the transistor 102 according to the present embodiment.

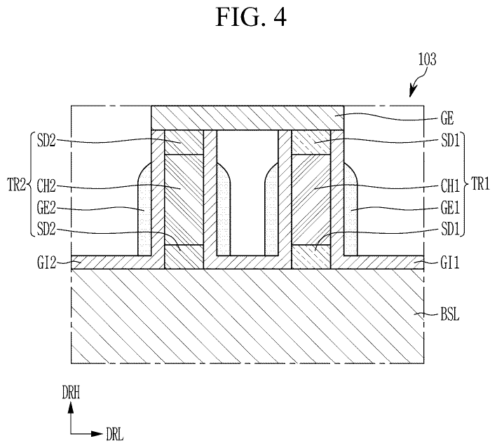

Referring to FIG. 4, a transistor 103 according to at least one example embodiment is described. FIG. 4 is a schematic cross-sectional view of a transistor according to at least one example embodiment.

Referring to FIG. 4, the transistor 103 according to the to the at least one example embodiment is similar to the transistors 100, 101, and 102 according to the embodiments described above. Therefore, detailed descriptions of the same components may be omitted, and the differences thereto mainly discussed below.

Referring to FIG. 4, the transistor 103 according to at least one example embodiment may include the first transistor TR1 and the second transistor TR2 on the base layer BSL.

Unlike the transistors 100, 101, and 102, the first transistor TR1 and the second transistor TR2 in the transistor 103 may be spaced apart from each other in the planar direction DRL, and the first transistor TR1 and the second transistor TR2 may not overlap each other in the height direction DRH.

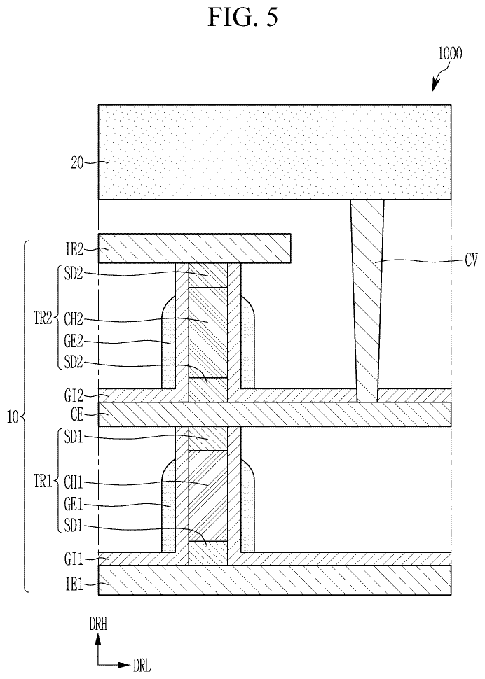

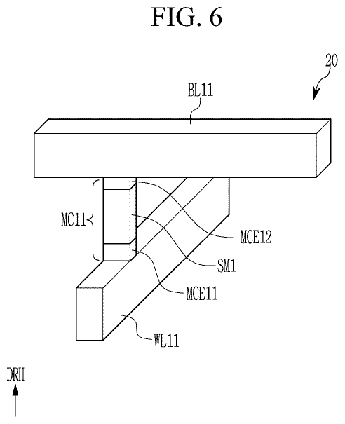

Referring to FIGS. 5 and 6, a semiconductor device 1000 including a transistor according to at least one example embodiment will be described. FIG. 5 is a schematic cross-sectional view illustrating a semiconductor device according to at least one example embodiment, and FIG. 6 is a schematic perspective view illustrating a portion of a semiconductor device according to at least one example embodiment.

Referring to FIG. 5, the semiconductor device 1000 according to at least one example embodiment may include a transistor structure 10 and a memory cell 20 connected to the transistor structure 10.

The memory cell 20 may be located on the transistor structure 10 in the height direction DRH.

The transistor structure 10 is similar to the transistor 100 according to the embodiment described above with reference to FIG. 1; however, the examples embodiments are not limited thereto. For example, the transistor structure may be (or be similar to) the transistors 101, 102, and/or 103.

The transistor structure 10 may include the first transistor TR1 and the second transistor TR2.

In the height direction DRH, the second transistor TR2 may be located on the first transistor TR1.

The first transistor TR1 and the second transistor TR2 may overlap at least partially in the height direction DRH.

The first transistor TR1 may be a p-type transistor, and the second transistor TR2 may be an n-type transistor. For example, the first channel region CH1 of the first transistor TR1 and the second channel region CH2 of the second transistor TR2 may have different conductivity types. For example, the first channel region CH1 of the first transistor TR1 may include a p-type semiconductor, and the second channel region CH2 of the second transistor TR2 may include an n-type semiconductor.

The first channel region CH1 of the first transistor TR1 and the second channel region CH2 of the second transistor TR2 may include different types of semiconductors. The first channel region CH1 of the first transistor TR1 may include silicon (e.g., crystalline and/or polycrystalline silicon). The second channel region CH2 of the second transistor TR2 may include an oxide semiconductor.

The first source drain regions SD1 may include a higher concentration of impurities (e.g., as dopants) than the first channel region CH1, and the second source drain regions SD2 may include a higher concentration of impurities (e.g., as dopants) than the second channel region CH2. For example, the first source drain regions SD1 may be doped with an n-type impurity, and the second source drain regions SD2 may be doped with a p-type impurity, but the embodiment is not limited thereto.

The first channel region CH1 of the first transistor TR1, which is a p-type transistor, includes crystalline and/or polycrystalline silicon, thereby increasing the mobility of the first transistor TR1 and preventing (or reducing the probability of) the movement and formation of holes from being limited, and the second channel region CH2 of the second transistor TR2, which is an n-type transistor, includes an oxide semiconductor, thereby reducing the leakage current of the second transistor TR2, and since the manufacturing of the second transistor TR2 does not include a high process temperature, it is possible to reduce damage to the first transistor TR1 and other elements under the second transistor TR2 during formation of the second transistor TR2.

The connection electrode CE may be located between one of the first source drain regions SD1 of the first transistor TR1 and one of the source drain regions SD2 of the second transistor TR2, thereby allowing the first transistor TR1 and the second transistor TR2 to form the CMOS transistor.

The connection electrode CE may be connected to the memory cell 20 through a connection via CV in the insulating layer IL.

An additional connection structure may be located between the transistor structure 10 and the memory cell 20, and the memory cell 20 may be connected to the transistor structure 10 through the connection via CV and the additional connection structure.

The first source drain regions SD1 of the first transistor TR1 may be connected to a first input electrode IE1 and the connection electrode CE, respectively, and the second source drain regions SD2 of the second transistor TR2 may be connected to a second input electrode IE2 and the connection electrode CE, respectively.

Although not shown, the first gate electrode GE1 of the first transistor TR1 and the second gate electrode GE2 of the second transistor TR2 may be connected to a control electrode GTE to be described later.

Referring to FIG. 6, the memory cell 20 of the semiconductor device 1000 may include a first electrode MCE11, a switch memory SM1 stacked on the first electrode MCE11, and a second electrode MCE12 stacked on a switch memory SM1. In at least some embodiments, the switch memory SM1 may correspond to (e.g., be and/or include) the semiconductor device 1000.

The first electrode MCE11 may contact a corresponding word line WL11, the second electrode MCE12 may contact a corresponding bit line BL11, and the switch memory SM1 may be located between the first electrode MCE11 and the second electrode MCE12. For example, the input electrodes IE1 and IE2 may be, respectively, connected to the corresponding word line WL11 and the corresponding bit line BL11.

The switch memory SM1 is a structure in which a switching element and a memory element are combined and may be an Ovonyx threshold switch (OTS). For example, the Ovonyx threshold switch may include a chalcogenide. When the voltage applied to both ends of the switch memory SM1 is lower than a predetermined threshold, no current flows through the switch memory SM1, and when the voltage exceeds a predetermined reference voltage, the current may rapidly increase in the switch memory SM1. According to at least one example embodiment, the switch memory SM1 may be an oxide-based switching selector utilizing the metal-insulator transition phenomenon of an oxide. However, the example embodiments are not limited thereto.

In FIG. 6, for convenience of description, the memory SM1 located at the intersection of one word line WL11, one bit line BL11, and the two signal lines WL11 and BL11 area shown, but the semiconductor device 1000 may include a plurality of memory cells 20 stacked in the planar direction DRL and the height direction DRH.

According to at least one example embodiment, the second transistor TR2 may be located on the first transistor TR1 in the height direction DRH, so that a planar area occupied by the first transistor TR1 and the second transistor TR2 may be reduced, and a vertical channel transistor having a channel direction parallel to the height direction DRH may be formed in a narrow planar area.

The memory cell 20 may be located on the transistor structure 10, so that the transistor structure 10 for driving the memory cell 20 overlaps with the memory cell 20 in the height direction DRH, thereby reducing the planar area occupied by the semiconductor device 1000.

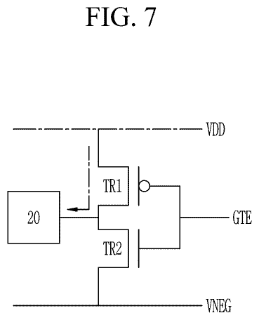

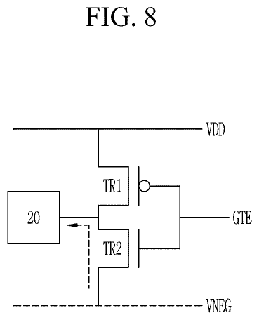

With reference to FIGS. 5 and 6, in conjunction with FIGS. 7 and 8, the operation of the semiconductor device 1000 will be described.

FIGS. 7 and 8 are circuit diagrams for operations of a semiconductor device according to at least one example embodiment.

A selected voltage VDD and a de-selected voltage VNEG may be applied to the memory cell 20 through the transistor structure 10.

When a low voltage is applied to the control electrode GTE, the p-type first transistor TR1 may be activated.

The selected voltage VDD input to the first input electrode IE1 may be applied to the connection electrode CE through the first transistor TR1, and the selected voltage VDD may be applied to the memory cell 20 through the connection electrode CE.

When a high voltage is applied to the control electrode GTE, the n-type second transistor TR2 may be activated.

The de-selected voltage VNEG input to the second input electrode IE2 may be applied to the connection electrode CE through the second transistor TR2, and the de-selected voltage VNEG may be applied to the memory cell 20 through the connection electrode CE.

According to at least one example embodiment, the selected voltage VDD is applied to the memory cell 20 through the first transistor TR1 including high-mobility crystalline silicon, thereby reducing occurrence of a delay time of the memory cell 20, and the de-selected voltage VNEG is applied to the memory cell 20 through the second transistor TR2 including an oxide semiconductor with low leakage current, which may reduce the occurrence of leakage current in the memory cell 20 and improve power.

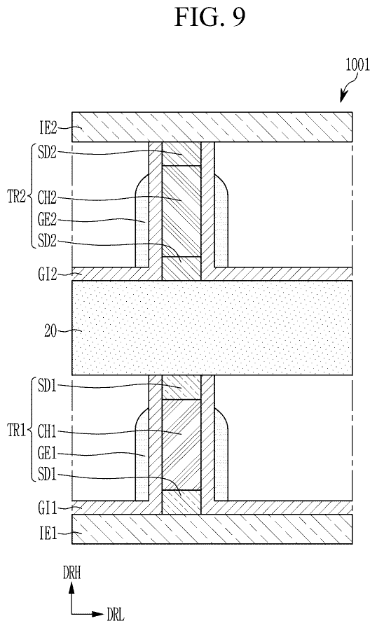

Referring to FIG. 9, a semiconductor device 1001 according to at least one example embodiment is described. FIG. 9 is a schematic cross-sectional view of a semiconductor device according to at least one example embodiment.

Referring to FIG. 9, the semiconductor device 1001 according to the embodiment is similar to the semiconductor device 1000 according to the embodiment described with reference to FIGS. 5 to 8. Therefore, detailed descriptions of like components and like operations may be omitted and the differences thereto mainly discussed.

Referring to FIG. 9, the semiconductor device 1001 according to at least one example embodiment may include the transistor structure 10 including the first transistor TR1 and the second transistor TR2 and the memory cell 20 connected thereto.

The memory cell 20 may be located between the first transistor TR1 and the second transistor TR2 in the height direction DRH.

The first transistor TR1 and the second transistor TR2 may overlap at least partially in the height direction DRH.

The first transistor TR1 may be a p-type transistor, and the second transistor TR2 may be an n-type transistor. For example, the first channel region CH1 of the first transistor TR1 and the second channel region CH2 of the second transistor TR2 may have different conductivity types. For example, the first channel region CH1 of the first transistor TR1 may include a p-type semiconductor, and the second channel region CH2 of the second transistor TR2 may include an n-type semiconductor.

The first channel region CH1 of the first transistor TR1 and the second channel region CH2 of the second transistor TR2 may include different types of semiconductors. The first channel region CH1 of the first transistor TR1 may include silicon, and the first channel region CH1 of the first transistor TR1 may include crystalline silicon. The second channel region CH2 of the second transistor TR2 may include an oxide semiconductor.

The first source drain regions SD1 may include a higher concentration of impurities (e.g., as dopants) than the first channel region CH1, and the second source drain regions SD2 may include a higher concentration of impurities (e.g., as dopants) than the second channel region CH2. For example, the first source drain regions SD1 may be doped with an n-type impurity, and the second source drain regions SD2 may be doped with a p-type impurity, but the example embodiments are not limited thereto.

The first channel region CH1 of the first transistor TR1, which is a p-type transistor, includes crystalline and/or polycrystalline silicon, thereby increasing the mobility of the first transistor TR1 and preventing (or reducing the potential for) the movement and formation of holes from being limited, and the second channel region CH2 of the second transistor TR2, which is an n-type transistor, includes an oxide semiconductor, thereby reducing the leakage current of the second transistor TR2, and since the manufacturing of the second transistor TR2 does not include a high process temperature, it is possible to reduce damage to the first transistor TR1 and other elements under the second transistor TR2 during formation of the second transistor TR2.

The first source drain regions SD1 of the first transistor TR1 may be connected to the first input electrode IE1 and the memory cell 20, respectively, and the second source drain regions SD2 of the second transistor TR2 may be connected to the second input electrode IE2 and the memory cell 20, respectively.

The first gate electrode GE1 of the first transistor TR1 and the second gate electrode GE2 of the second transistor TR2 may be connected to the control electrode GTE.

The selected voltage VDD and the de-selected voltage VNEG may be applied to the memory cell 20 through the transistor structure 10.

The selected voltage VDD is applied to the memory cell 20 through the first transistor TR1 including high-mobility crystalline silicon, thereby reducing occurrence of a delay time of the memory cell 20, and the de-selected voltage VNEG is applied to the memory cell 20 through the second transistor TR2 including an oxide semiconductor with low leakage current, which may reduce the occurrence of leakage current in the memory cell 20 and improve power.

According to at least one example embodiment, the first transistor TR1 and the second transistor TR2 may overlap in the height direction DRH, so that the planar area occupied by the first transistor TR1 and the second transistor TR2 may be reduced, and a vertical channel transistor having a channel direction parallel to the height direction DRH may be formed in a narrow planar area.

The memory cell 20 may be located on the transistor structure 10, so that the transistor structure 10 for driving the memory cell 20 overlaps with the memory cell 20 in the height direction DRH, thereby reducing the planar area occupied by the semiconductor device 1001.

Many of the features of the semiconductor device 1000 according to the embodiment described above with reference to FIGS. 5 to 8 are applicable to the semiconductor device 1001 according to the example embodiments.

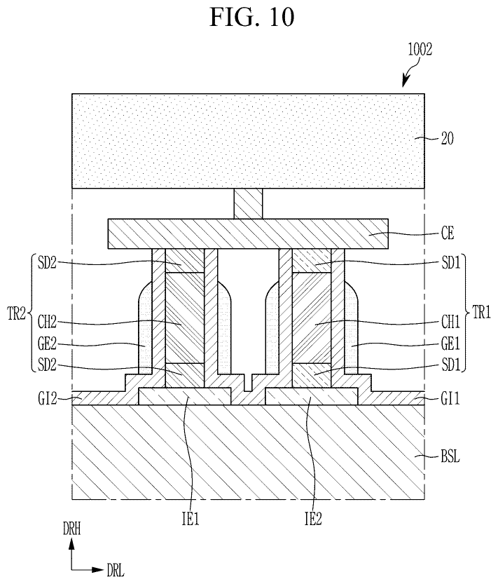

Referring to FIG. 10, a semiconductor device 1002 according to at least one example embodiment is described. FIG. 10 is a schematic cross-sectional view of a semiconductor device according to at least one example embodiment.

Referring to FIG. 10, the semiconductor device 1002 according to the at least one example embodiment is similar to the semiconductor devices 1000 and 1001 according to the embodiments described above. Therefore, detailed descriptions of like components and like operations may be omitted and the differences thereto mainly described.

Referring to FIG. 10, the semiconductor device 1002 according to at least one example embodiment may include the transistor structure 10 including the first transistor TR1 and the second transistor TR2 and the memory cell 20 connected thereto.

The memory cell 20 may be located on the transistor structure 10 in the height direction DRH.

The first transistor TR1 and the second transistor TR2 may overlap at least partially in the planar direction DRL.

The first transistor TR1 may be a p-type transistor, and the second transistor TR2 may be an n-type transistor.

The first channel region CH1 of the first transistor TR1 and the second channel region CH2 of the second transistor TR2 may include different types of semiconductors. The first channel region CH1 of the first transistor TR1 may include silicon, and the first channel region CH1 of the first transistor TR1 may include crystalline and/or polycrystalline silicon. The second channel region CH2 of the second transistor TR2 may include an oxide semiconductor.

The first channel region CH1 of the first transistor TR1 and the second channel region CH2 of the second transistor TR2 may have different conductivity types. For example, the first channel region CH1 of the first transistor TR1 may include a p-type semiconductor, and the second channel region CH2 of the second transistor TR2 may include an n-type semiconductor.

The first source drain regions SD1 may include a higher concentration of impurities (e.g., as dopants) than the first channel region CH1, and the second source drain regions SD2 may include a higher concentration of impurities (e.g., as dopants) than the second channel region CH2. For example, the first source drain regions SD1 may be doped with an n-type impurity, and the second source drain regions SD2 may be doped with a p-type impurity, but the embodiment is not limited thereto.

The first channel region CH1 of the first transistor TR1, which is a p-type transistor, includes crystalline and/or polycrystalline silicon, thereby increasing the mobility of the first transistor TR1 and preventing (or reducing the potential for) the movement and formation of holes from being limited, and the second channel region CH2 of the second transistor TR2, which is an n-type transistor, includes an oxide semiconductor, thereby reducing the leakage current of the second transistor TR2, and since the manufacturing of the second transistor TR2 does not include a high process temperature, it is possible to reduce damage to the first transistor TR1 and other elements under the second transistor TR2 during formation of the second transistor TR2.

The first source drain regions SD1 of the first transistor TR1 may be connected to the first input electrode IE1 and the connection electrode CE, respectively, and the second source drain regions SD2 of the second transistor TR2 may be connected to the second input electrode IE2 and the connection electrode CE, respectively.

The first gate electrode GE1 of the first transistor TR1 and the second gate electrode GE2 of the second transistor TR2 may be connected to the control electrode GTE.

The selected voltage VDD and the de-selected voltage VNEG may be applied to the memory cell 20 through the transistor structure 10.

The selected voltage VDD is applied to the memory cell 20 through the first transistor TR1 including high-mobility crystalline silicon, thereby reducing occurrence of a delay time of the memory cell 20, and the de-selected voltage VNEG is applied to the memory cell 20 through the second transistor TR2 including an oxide semiconductor with low leakage current, which may reduce the occurrence of leakage current in the memory cell 20 and improve power.

According to at least one example embodiment, the memory cell 20 may be located on the transistor structure 10 including the first transistor TR1 and the second transistor TR2 having channel directions parallel to the height direction DRH, so that the transistor structure 10 for driving the memory cell 20 overlaps the memory cell 20 in the height direction DRH, thereby reducing the planar area occupied by the semiconductor device 1002.

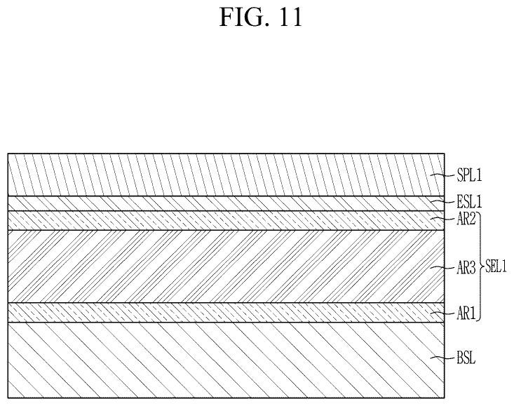

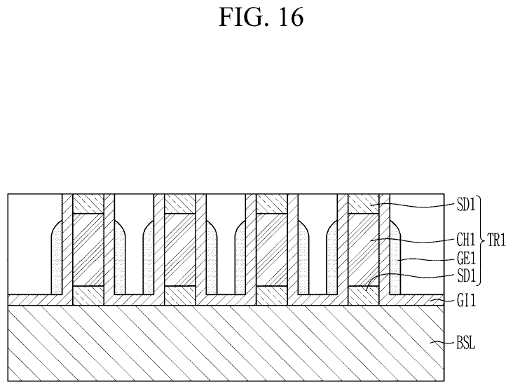

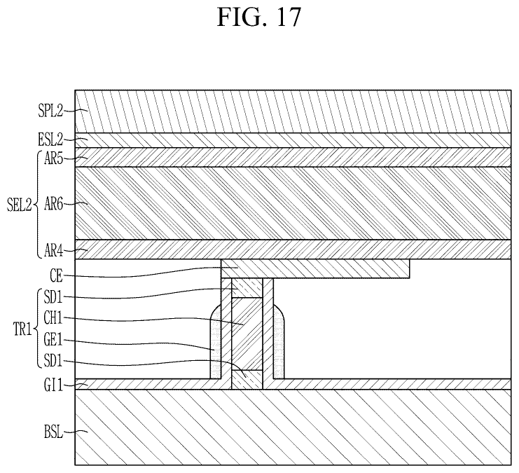

Referring to FIGS. 11 to 22 in conjunction with FIGS. 1 and 5, a method for manufacturing a semiconductor device according to at least one example embodiment will be described. FIGS. 11 to 22 are cross-sectional views illustrating a method for manufacturing a semiconductor device according to at least one example embodiment. For ease of description, the orientation of the manufacturing of the semiconductor device is changed between FIGS. 16 and 17.

Referring to FIG. 11, a first semiconductor layer SEL1 including a first region AR1 and a second region AR2 that are highly doped on the base layer BSL, and a third region AR3 that is located between the first region AR1 and the second region AR2 may be formed, a first etching stop layer ESL1 may be formed on the first semiconductor layer SEL1, and a first spacer layer SPL1 may be formed on the first etching stop layer ESL1.

The first semiconductor layer SEL1 may be formed by stacking silicon layers and then crystallizing the silicon layers. Thereby, the first semiconductor layer SEL1 may include crystalline silicon and/or may include polycrystalline silicon.

The first semiconductor layer SEL1 may include a p-type semiconductor. For example, the first semiconductor layer SEL1 may be doped with acceptor impurities which have a lower valency than the semiconductor such that acceptor charge carriers (e.g., holes) are available in the p-type semiconductor.

The first region AR1 and the second region AR2 may be doped with n-type impurities. For example, the first region AR1 and the second region AR2 may both be doped with donator impurities which have a higher valency than the semiconductor such that donator charge carriers (e.g., electrons) are available in the n-type semiconductor.

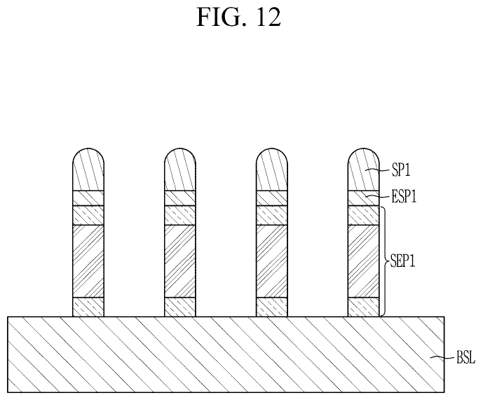

Referring to FIG. 12, the first spacer layer SPL1, the first etching stop layer ESL1, and the first semiconductor layer SEL1 may be etched to form a first semiconductor pattern SEP1, a first etching stop pattern ESP1, and a first spacer SP1. For example, a mask may be applied and the first spacer layer SPL1, the first etching stop layer ESL1, and the first semiconductor layer SEL1 may be etched using a wet and/or dry etch.

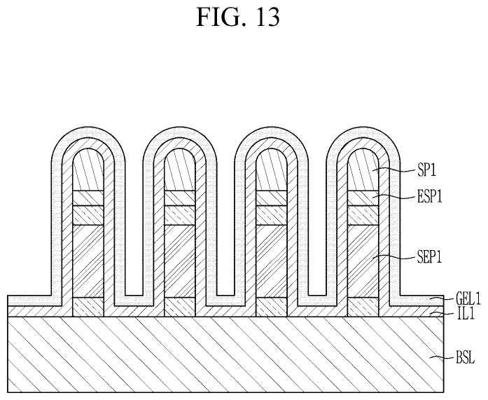

Referring to FIG. 13, a first insulating layer IL1 and a first gate metal layer GEL1 may be conformally stacked on the first semiconductor pattern SEP1, the first etching stop pattern ESP1, and the first spacer SP1.

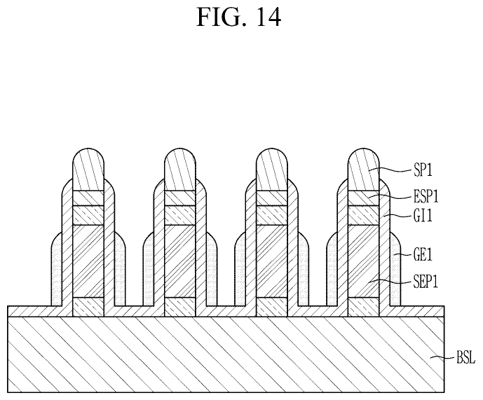

Referring to FIG. 14, the first gate metal layer GEL1 and the first insulating layer IL1 may be etched to form the first gate electrode GE1 and the first gate insulating film GI1.

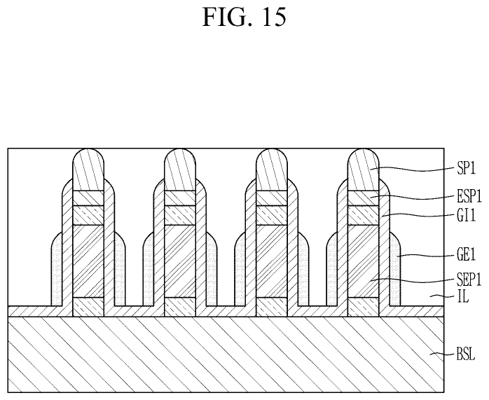

Referring to FIG. 15, the insulating layer IL may be stacked to cover the first semiconductor pattern SEP1, the first etching stop pattern ESP1, the first spacer SP1, the first gate electrode GE1, and the first gate insulating film GI1.

Referring to FIG. 16, parts of the insulating layer IL, the first spacer layer SPL1, the first etching stop layer ESL1, and the first gate insulating film GI1 may be removed by a method such as planarization to form the first transistor TR1 including the first channel region CH1, first source drain regions SD1 located on opposite sides of the first channel region CH1 in the height direction DRH, and the first gate electrode GE1 located on a side of the first channel region CH1 with the first gate insulating film GI1 interposed between the first channel region CH1 and the first gate electrode GE1 in the planar direction DRL.

Referring to FIG. 17, the connection electrode CE contacting one of the first source drain regions SD1 of the first transistor TR1 may be formed, a second semiconductor layer SEL2 which includes a fourth region AR4 and a fifth region AR5 doped at a high concentration, and a sixth region AR6 located between the fourth region AR4 and the fifth region AR5 may be formed, a second etching stop layer ESL2 may be formed on the second semiconductor layer SEL2, and a second spacer layer SPL2 may be formed on the second etching stop layer ESL2.

For convenience of description, in FIG. 17 and below, one first transistor TR1 and one second transistor TR2 are illustrated. However, the example embodiments are not limited thereto, and the examples embodiments are applicable to a process of forming a plurality of second transistors TR2 on a plurality of first transistors TR1.

The second semiconductor layer SEL2 may include an oxide semiconductor. The second semiconductor layer SEL2 includes an oxide semiconductor and does not undergo a crystallization operation, so the process temperature may be relatively low. Accordingly, it is possible to prevent the first transistor TR1 formed before the formation of the second semiconductor layer SEL2 from being damaged by the process temperature, and to form the second semiconductor layer SEL2 by directly stacking it on top of the first transistor TR1.

The second semiconductor layer SEL2 may include an n-type semiconductor.

The fourth region AR4 and fifth region AR5 may be doped with p-type impurities.

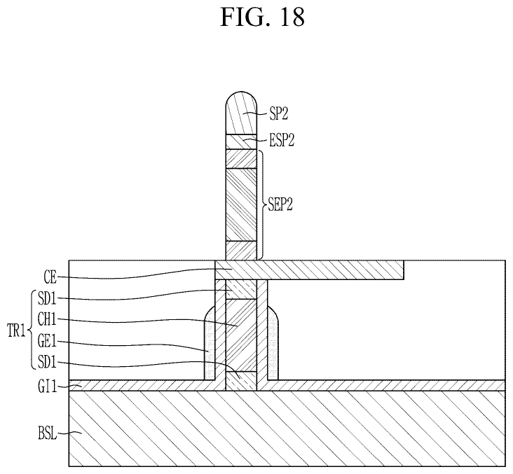

Referring to FIG. 18, the second spacer layer SPL2, the second etching stop layer ESL2, and the second semiconductor layer SEL2 may be etched to form a second semiconductor pattern SEP2, a second etching stop pattern ESP2, and a second spacer SP2.

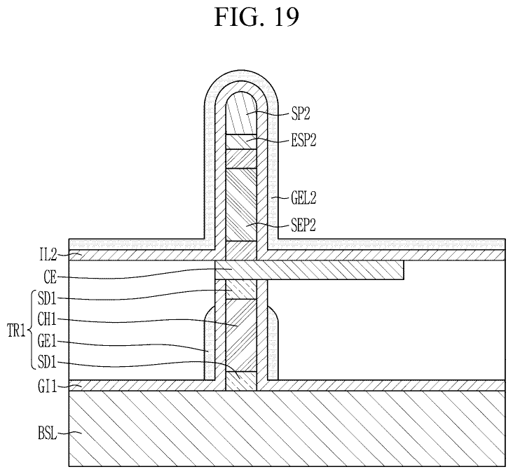

Referring to FIG. 19, a second insulating layer IL2 and a second gate metal layer GEL2 may be conformally stacked on the second semiconductor pattern SEP2, the second etching stop pattern ESP2, and the second spacer SP2.

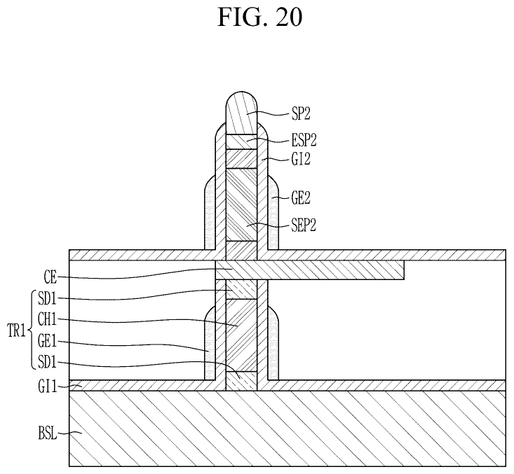

Referring to FIG. 20, the second gate metal layer GEL2 and the second insulating layer IL2 may be etched to form the second gate electrode GE2 and the second gate insulating film GI2.

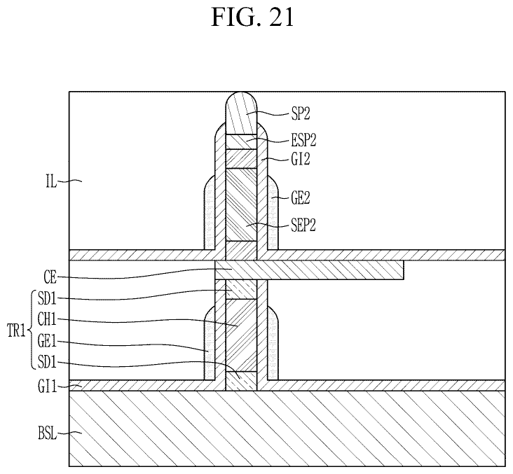

Referring to FIG. 21, the insulating layer IL may be stacked to cover the second semiconductor pattern SEP2, the second etching stop pattern ESP2, the second spacer SP2, the second gate electrode GE2, and the second gate insulating film GI2.

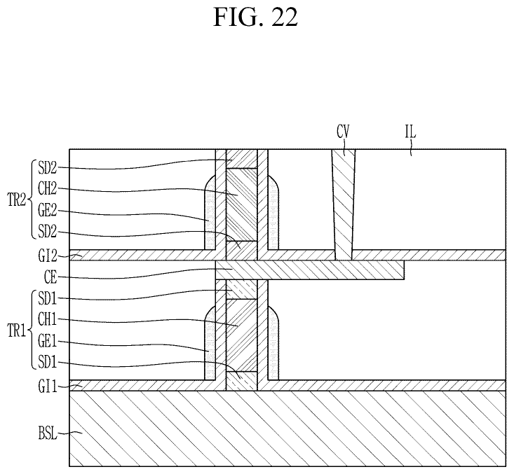

Referring to FIG. 22, parts of the insulating layer IL, the second spacer layer SPL2, the second etching stop layer ESL2, and the second gate insulating film GI2 may be removed by a method such as planarization to form the second transistor TR2 including the second channel region CH2, second source drain regions SD2 located on opposite sides of the second channel region CH2 in the height direction DRH, and the second gate electrode GE2 located on the side surface of the second channel region CH2 with the second gate insulating film GI2 interposed between the second channel region CH2 and the second gate electrode GE2 in the planar direction DRL. The connection via CV connected to the connection electrode CE may be formed in the insulating layer IL as required.

The memory cell 20 connected to the connection electrode CE may be further formed through the connection via CV.

According to at least one example embodiment, after forming a p-type first transistor TR1 including crystalline silicon, an n-type second transistor TR2 including an oxide semiconductor is formed thereon, thereby forming an oxide semiconductor after crystallizing the silicon. Therefore, while forming the second transistor TR2, the previously formed first transistor TR1 may not be damaged by the process temperature.

If both the first transistor TR1 and the second transistor TR2 are formed to include crystalline silicon, the first transistor TR1 may be damaged by the high process temperature for crystallization during the formation process of the second transistor TR2, so it is difficult to directly form the second transistor TR2 on the first transistor TR1, and the first transistor TR1 and the second transistor TR2 are formed separately and then connected by a wafer bonding. The wafer bonding may complicate the process and increase process costs.

However, according to at least one example embodiment, by forming the p-type first transistor TR1 including crystalline or polycrystalline silicon and then forming the n-type second transistor TR2 including an oxide semiconductor thereon, it is possible to form the first transistor TR1 and the second transistor TR2 having a channel direction parallel to the height direction DRH to overlap each other in the height direction DRH without increasing the manufacturing cost or causing damage to the device due to the process temperature.

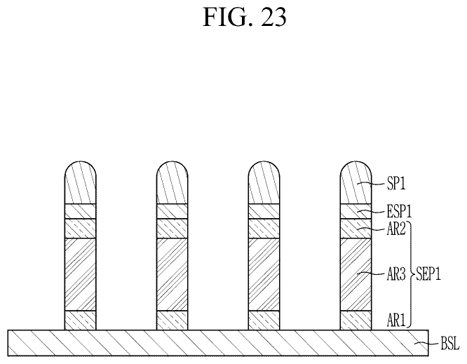

Referring to FIG. 2 and FIGS. 23 to 30, a method for manufacturing a semiconductor device according to at least one example embodiment will be described. FIGS. 23 to 30 are cross-sectional views illustrating a method for manufacturing a semiconductor device according to at least one example embodiment.

Referring to FIG. 23, the first semiconductor pattern SEP1 and the first spacer SP1 may be formed on the base layer BSL. The first semiconductor pattern SEP1 may include the first region AR1 and the second region AR2 doped at a high concentration, and the third region AR3 located between the first region AR1 and the second region AR2.

Similar to the manufacturing method according to the embodiment described above, the first semiconductor layer SEL1 may be formed on the base layer BSL, the first spacer layer SPL1 may be formed on the first semiconductor layer SEL1, and then etched to form the first semiconductor pattern SEP1 and the first spacer SP1.

The first semiconductor pattern SEP1 may include crystalline silicon or may include polycrystalline silicon. The first semiconductor pattern SEP1 may be formed by stacking silicon layers and then crystallizing the silicon layers.

The first semiconductor pattern SEP1 may include a p-type semiconductor.

The first region AR1 and the second region AR2 may be doped with n-type impurities.

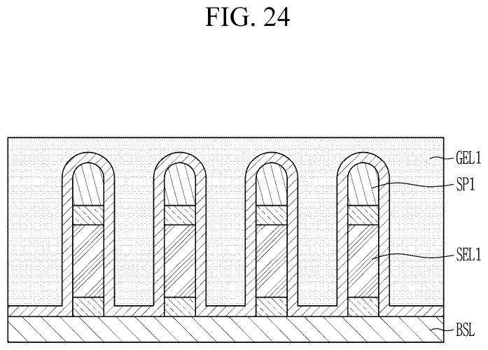

Referring to FIG. 24, after the first insulating layer IL1 is conformally stacked on the first spacer SP1 and the first semiconductor layer SEL1, the first gate metal layer GEL1 may be stacked to have a flat surface.

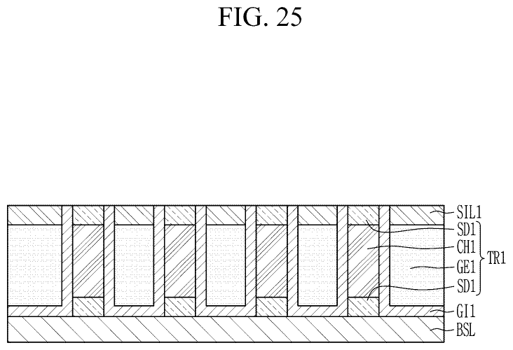

Referring to FIG. 25, the first gate metal layer GEL1 may be etched and/or planarized to form the first gate electrode GE1, the separation insulating layers SIL1 may be formed on the first gate electrode GE1, and the first spacer SP1 and the first insulating layer IL1 may be etched and/or planarized to form the first gate insulating film GI1. Through this, the first transistor TR1 may be formed that includes the first channel region CH1, first source drain regions SD1 located on opposite sides of the first channel region CH1 in the height direction DRH, and the first gate electrode GE1 located on a side surface of the first channel region CH1 with the first gate insulating film GI1 interposed between the first channel region CH1 and the first gate electrode GE1 in the planar direction DRL.

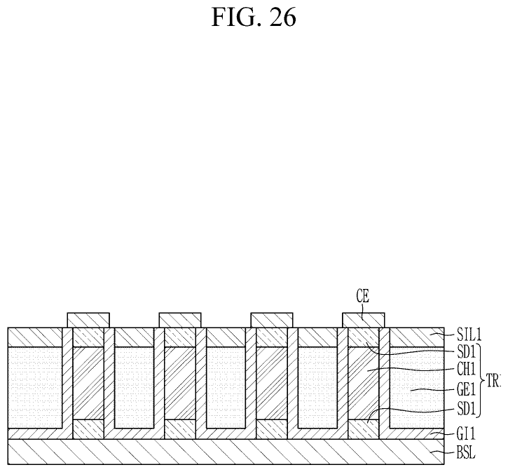

Referring to FIG. 26, the connection electrodes CE may be formed on the first source drain regions SD1 of the first transistor TR1.

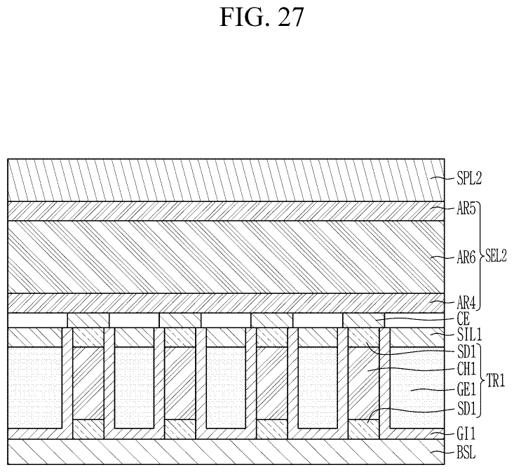

Referring to FIG. 27, the second semiconductor layer SEL2 including the fourth region AR4 and the fifth region AR5 doped at a high concentration and the sixth region AR6 located between the fourth region AR4 and the fifth region AR5 may be formed on the first transistor TR1 and the connection electrode CE, and the second spacer layer SPL2 may be formed on the second semiconductor layer SEL2.

The second semiconductor layer SEL2 may include an oxide semiconductor. The second semiconductor layer SEL2 includes an oxide semiconductor and does not crystallize, so the process temperature may be relatively low. Accordingly, it is possible to prevent the first transistor TR1 formed before the formation of the second semiconductor layer SEL2 from being damaged by the process temperature, and to form the second semiconductor layer SEL2 by directly stacking it on top of the first transistor TR1.

The second semiconductor layer SEL2 may include an n-type semiconductor.

The fourth region AR4 and the fifth region AR5 may be doped with p-type impurities.

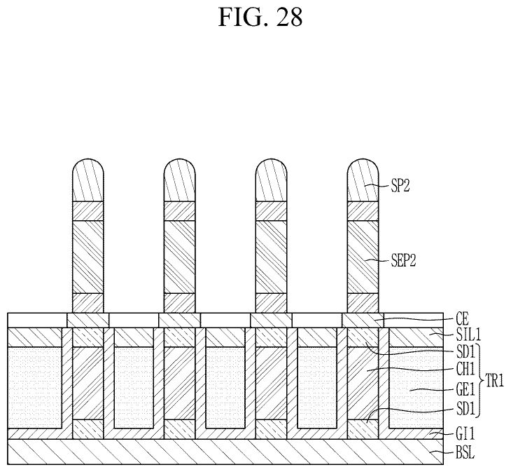

Referring to FIG. 28, the second spacer layer SPL2 and the second semiconductor layer SEL2 may be etched to form the second semiconductor pattern SEP2 and the second spacer SP2.

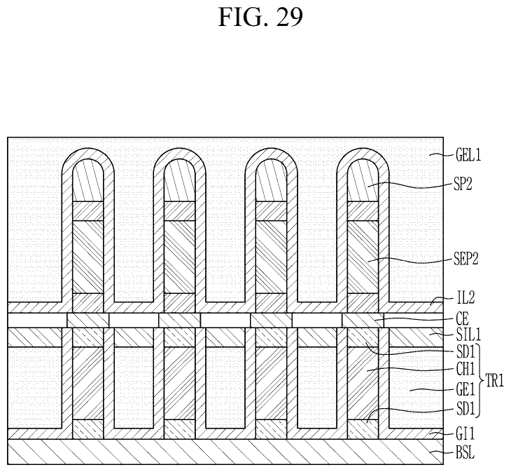

Referring to FIG. 29, the second insulating layer IL2 may be conformally stacked on the second semiconductor pattern SEP2 and the second spacer SP2, and the second gate metal layer GEL2 may be stacked to have a flat surface.

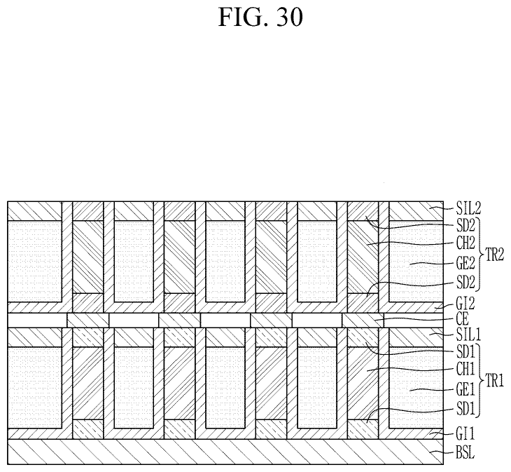

Referring to FIG. 30, the second gate metal layer GEL2 may be etched to form the second gate electrode GE2, the second spacer SP2 and the second insulating layer IL2 may be etched to form the second gate insulating film GI2, and the separation insulating layer SIL2 may be formed on the second gate electrode GE2.

This enables formation of the second transistor TR2 that includes the second channel region CH2, the second source drain regions SD2 located on opposite sides of the second channel region CH2 in the height direction DRH, and the second gate electrode GE2 located on the side surface of the second channel region CH2 with the second gate insulating film GI2 interposed between the second channel region CH2 and the second gate electrode GE2 in the planar direction DRL.

In at least some example embodiments, the connection via CV connected to the connection electrode CE may be formed in the insulating layer IL, and the memory cell 20 connected to the connection electrode CE through the connection via CV may be further formed.

According to at least one example embodiment, after forming a p-type first transistor TR1 including crystalline (or polycrystalline) silicon, an n-type second transistor TR2 including an oxide semiconductor is formed thereon, thereby forming an oxide semiconductor after crystallizing the silicon. According to at least one example embodiment, while forming the second transistor TR2, the previously formed first transistor TR1 may not be damaged by the process temperature. Accordingly, it is possible to form the first transistor TR1 and the second transistor TR2 having a channel direction parallel to the height direction DRH to overlap each other in the height direction DRH without increasing the manufacturing cost or causing damage to the device due to the process temperature.

While some example embodiments of the present disclosure have been described in detail, it is to be understood that the disclosure is not limited to the disclosed embodiments, but on the contrary, is intended to cover various modifications and equivalent arrangements included within the spirit and scope of the appended claims.

What is claimed is:

1. A transistor, comprising:
a first transistor located on a base layer and including a first channel region, the first channel region including at least one of crystalline or polycrystalline silicon; and
a second transistor located on the first transistor, overlapping at least a portion of the first transistor in a height direction, the second transistor including a second channel region, the second channel region including an oxide semiconductor.

2. The transistor of claim 1, wherein
the first channel region and the second channel region have different conductivity types.

3. The transistor of claim 2, wherein
the first channel region comprises a p-type semiconductor and the second channel region comprises an n-type semiconductor.

4. The transistor of claim 3, wherein
the first transistor comprises first source drain regions located, respectively, under and over the first channel region in the height direction, and
the second transistor comprises second source drain regions located, respectively, under and over the second channel region in the height direction.

5. The transistor of claim 4, wherein
one first source drain region of the first source drain regions and one second source drain region of the second source drain regions are electrically connected to each other.

6. The transistor of claim 5, further comprising:
a connection electrode electrically connecting the one first source drain region and the one second source drain region.

7. The transistor of claim 4, further comprising:
a first gate electrode on a side surface of the first channel region in a planar direction perpendicular to the height direction; and
a second gate electrode on a side surface of the second channel region in the planar direction.

8. A transistor, comprising:
a first transistor on a base layer, the first transistor including a first channel region and first source drain regions located, respectively, under and over the first channel region in a height direction, the first channel region including at least one of a crystalline or polycrystalline silicon; and
a second transistor on the base layer and located on a side surface of the first transistor, the second transistor including a second channel region and second source drain regions located, respectively, under and over the second channel region in the height direction, the second channel region including an oxide semiconductor.

9. The transistor of claim 8, wherein
the first channel region and the second channel region have different conductivity types.

10. The transistor of claim 9, wherein
the first channel region comprises a p-type semiconductor and the second channel region comprises an n-type semiconductor.

11. The transistor of claim 10, wherein
one first source drain region of the first source drain regions and one second source drain region of the second source drain regions are electrically connected to each other.

12. The transistor of claim 11, further comprising:
a connection electrode electrically connecting the one first source drain region and the one second source drain region,
wherein the connection electrode is on the first transistor and the second transistor.

13. A semiconductor device, comprising:
a transistor structure including a first transistor and a second transistor on a base layer, the first transistor including a first channel region, the second transistor including a second channel region, the second transistor located over the first transistor and at least partially overlapping the first transistor in a height direction; and
a memory cell connected to the transistor structure,
wherein the first channel region includes at least one of crystalline or polycrystalline silicon, and
the second channel region includes an oxide semiconductor.

14. The semiconductor device of claim 13, wherein
the first channel region and the second channel region have different conductivity types.

15. The semiconductor device of claim 14, wherein
the first channel region comprises a p-type semiconductor and the second channel region comprises an n-type semiconductor.

16. The semiconductor device of claim 15, wherein
the first transistor comprises first source drain regions located, respectively, under and over the first channel region in the height direction, and
the second transistor comprises second source drain regions located, respectively, under and over the second channel region in the height direction.

17. The semiconductor device of claim 16, wherein
one first source drain region of the first source drain regions and one second source drain region of the second source drain regions are electrically connected to each other.

18. The semiconductor device of claim 17, further comprising:
a connection electrode electrically connecting the one first source drain region and the one second source drain region.

19. The semiconductor device of claim 18, wherein
the memory cell is connected to the connection electrode.

20. The semiconductor device of claim 16, further comprising:
a first gate electrode on a side surface of the first channel region in a planar direction perpendicular to the height direction; and
a second gate electrode on a side surface of the second channel region in the planar direction.
